(19) United States
(12) Patent Application Publication
(10) Pub. No.: US 2024/0114647 A1
(43) Pub. Date: Apr. 4, 2024

(54) ELECTRONIC DEVICE

(71) Applicant: NIDEC CORPORATION, Kyoto (JP)

(72) Inventor: Takeru INAYOSHI, Kyoto (JP)

(21) Appl. No.: 18/476,318

(22) Filed: Sep. 28, 2023

(30) Foreign Application Priority Data
Sep. 29, 2022 (JP) 2022-155832

(51) Int. Cl. H05K 7/20

(52) U.S. Cl. CPC H05K 7/20145; H05K 7/20727

(57) ABSTRACT

A housing has an exhaust port and an intake port on one side and another side in a second direction, heat generators and fans arranged in a first direction, the fans on one side in the second direction of the heat generators, and an airflow restrictor between the heat generators and fans. The airflow restrictor includes a pair of guide portions arranged side by side with a first gap therebetween in the first direction. Each guide portion has an airflow guide surface facing the other side in the second direction and inclined toward the first gap. The housing includes a pair of first inner side surfaces facing each other in the first direction and a pair of second inner side surfaces facing each other in a third direction. A gap is between any one of the first inner side surfaces and the second inner side surfaces and the airflow restrictor.

### CROSS-REFERENCE TO RELATED APPLICATIONS

The present invention claims priority under 35 U.S.C. § 119 to Japanese Patent Application No. 2022-155832 filed on Sep. 29, 2022, the entire content of which is incorporated herein by reference.

### FIELD OF THE INVENTION

The present invention relates to an electronic device.

### BACKGROUND

In an electronic device having a plurality of heat generating components, a plurality of fans generate a flow of air in a housing to cool the heat generating components. In such an electronic device, when the air blowing amount of a part of the fans decreases, a region in which the flow velocity of the air locally decreases is generated in the housing, which may cause insufficient cooling of a part of the heat generating components. Conventionally, there is known a structure in which a partition plate having a throttle portion for concentrating an air flow is provided between a fan and a heat generating component to uniformly cool each heat generating component even if a part of the fan fails.

In the partition plate of the conventional technique, the air flow cannot be sufficiently uniformized, the unevenness occurs in the air volume depending on the location of the heat generating component, and the reliability of the cooling structure cannot be sufficiently enhanced.

### SUMMARY

According to one aspect of the present invention, there is provided: a housing having a box shape with a first direction, a second direction, and a third direction orthogonal to each other as respective plane directions, an exhaust port being provided at an end portion on one side in the second direction, and an intake port being provided at an end portion on an other side in the second direction; a plurality of heat generators arranged in the first direction in the housing; a plurality of fans arranged in the first direction in the housing, arranged on one side in the second direction with respect to the plurality of heat generators, and configured to generate an airflow on one side in the second direction in the housing; and an airflow restrictor positioned between the plurality of heat generators and the plurality of fans in the housing. The airflow restrictor includes a pair of guide portions arranged side by side with the first gap interposed therebetween in the first direction. Each of the pair of guide portions has an airflow guide surface facing the other side in the second direction and inclined toward the first gap side. The inner side surface of the housing includes a pair of first inner side surfaces facing each other in the first direction and a pair of second inner side surfaces facing each other in the third direction. A gap is provided between any one of the pair of first inner side surfaces and the pair of second inner side surfaces and the airflow restrictor.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of an electronic device according to a first embodiment;

FIG. 2 is an exploded view of a first heat generator of the first embodiment;

FIG. 3 is a plan view illustrating a part of the electronic device of the first embodiment;

FIG. 4 is a cross-sectional view of the electronic device of the first embodiment taken along line IV-IV of FIG. 3; and

FIG. 5 is a plan view illustrating a part of an electronic device according to a second embodiment.

### DETAILED DESCRIPTION

Hereinafter, embodiments of the present invention will be described with reference to the drawings.

Each drawing illustrates a first direction D1, a second direction D2, and a third direction D3. The first direction D1, the second direction D2, and the third direction D3 are directions orthogonal to each other. Hereinafter, each part of an electronic device 1 will be described based on the first direction D1, the second direction D2, and the third direction. In the following description, the direction of each unit of the electronic device 1 may be described with one side (+D3 side) in the third direction as the upper side. However, the posture of the electronic device 1 at the time of use is an example, and is not limited to the following embodiment.

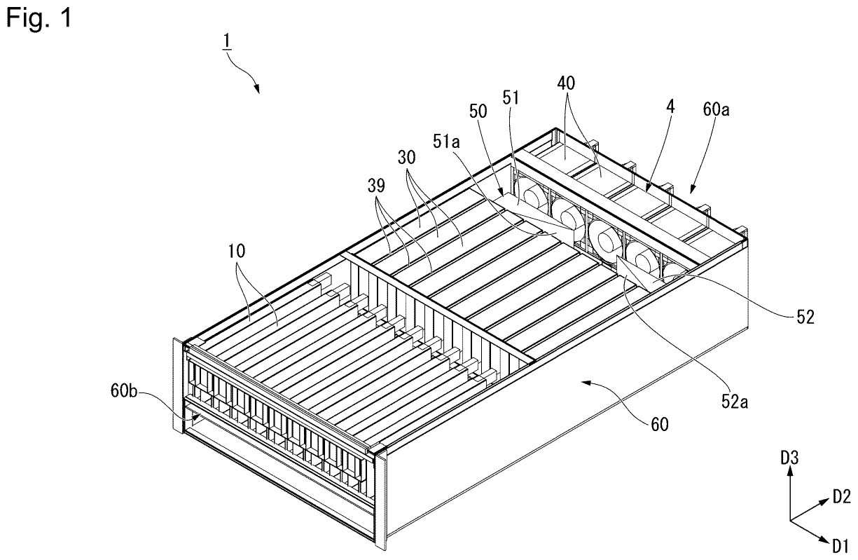

FIG. 1 is a perspective view of the electronic device 1 according to a first embodiment. The electronic device 1 of the present embodiment is a calculation server. However, the application of the electronic device 1 is not limited to the present embodiment.

The electronic device 1 includes a plurality of first heat generators (heat generators) 30, a plurality of second heat generators 10, a cooling device 4, an airflow restrictor 50, and a housing 60 that houses these components. In FIG. 1, the housing 60 is illustrated in a state where the upper lid portion is removed.

The housing 60 has a box shape with the first direction D1, the second direction D2, and the third direction D3 as respective plane directions. The housing 60 is made of, for example, a metal material.

The housing 60 is provided with an exhaust port 60a and an intake port 60b. The exhaust port 60a is provided at an end portion on one side (+D2 side) in the second direction of the housing 60. The intake port 60b is provided at an end portion on the other side (−D2 side) in the second direction of the housing 60. The exhaust port 60a and the intake port 60b are provided by opening side walls on both sides in the second direction of the housing 60. The air is taken into the housing 60 from the intake port 60b and discharged to the outside of the housing 60 at the exhaust port 60a. The air flows from the other side (−D2 side) in the second direction toward one side (+D2 side) in the second direction in the housing 60.

The plurality of first heat generators 30 are arranged in the first direction D1 in the housing 60. The electronic device 1 according to the present embodiment is provided with ten first heat generators 30. The first heat generator 30 has a substantially rectangular parallelepiped shape. A slight gap is provided between the first heat generators 30 arranged in the first direction D1. A seal member 39 is disposed between the first heat generators 30 adjacent to each other. The seal member 39 closes a gap between the first heat generators 30.

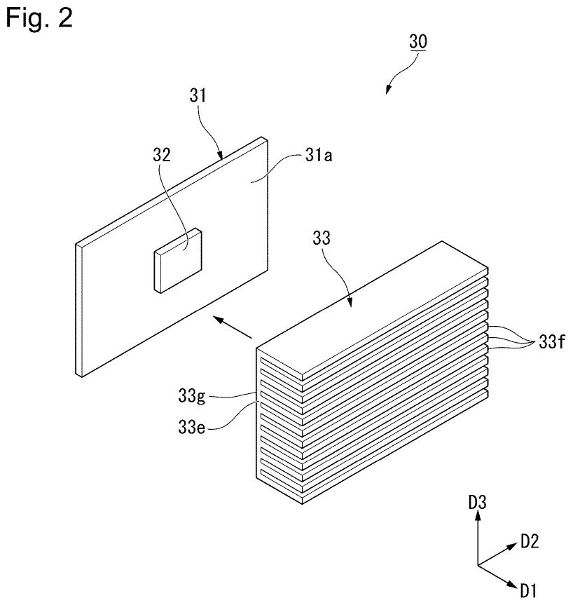

FIG. 2 is an exploded view of the first heat generator 30.

The first heat generator 30 includes a board 31, a heat element 32, and a heat sink 33.

The board 31 is a rigid board, and a circuit is provided on the surface and inside. The board 31 has a mounting surface 31a extending along a direction orthogonal to the first direction D1. The mounting surface 31a faces one side (+D1 side) in the first direction. The heat element 32 is mounted on the mounting surface 31a. In addition, another element may be mounted on the board 31.

The board 31 may be connected to the board 31 of another first heat generator 30. In this case, the boards 31 are connected to each other via a main board (not illustrated) or the like. The main board is located on the other side (−D3 side) in the third direction with respect to the board 31 and extends along a plane orthogonal to the third direction D3.

The heat element 32 is an image processing element such as a graphics processing unit (GPU). However, the type of the heat element 32 is not limited as long as it is an element that generates heat in accordance with driving. In addition to the heat element 32 described above, another heat element may be mounted on the board 31.

The heat sink 33 is made of a metal material having high heat conductivity such as an aluminum alloy. At least one heat sink 33 is attached to each heat element 32. The heat sink 33 includes a base plate 33e and a plurality of fins 33f.

The base plate 33e extends along the mounting surface 31a of the board 31. That is, the base plate 33e extends along a direction orthogonal to the first direction D1. The base plate 33e has a heat absorbing surface 33g facing the other side (−D2 side) in the first direction. The heat absorbing surface 33g faces the heat element 32. The heat absorbing surface 33g may be in direct contact with the heat element 32 or may be in contact with the heat element 32 via a flowable heat transfer material such as heat radiation grease. In either case, the heat of the heat element 32 is transferred to the heat absorbing surface 33g of the heat sink 33.

The plurality of fins 33f are provided on the surface on one side (+D1 side) in the first direction of the base plate 33e. Each of the fins 33f has a rectangular shape. Each of the fins 33f extends along a plane orthogonal to the third direction D3. The plurality of fins 33f are arranged along the third direction D3 with a gap interposed therebetween. That is, the heat sink 33 has a plurality of fins 33f arranged in one direction (the third direction D3 in the present embodiment). The air generated by the cooling device 4 to be described later passes between the fins 33f. As a result, the heat transferred from the heat element 32 to the heat sink 33 is transferred to the air. That is, the heat sink 33 dissipates the heat of the heat element 32.

As illustrated in FIG. 1, the second heat generator 10 is disposed on the other side (−D2 side) in the second direction with respect to the first heat generator 30. The plurality of second heat generators 10 are arranged in the first direction D1 in the housing 60. The electronic device 1 according to the present embodiment is provided with ten second heat generators 10. The second heat generator 10 includes a heat element (not illustrated) similarly to the first heat generator 30. The calorific value of the heat element of the second heat generator 10 is smaller than the calorific value of the heat element 32 of the first heat generator 30.

The cooling device 4 is disposed at an end portion on one side (+D2) in the second direction in the housing 60. Therefore, the cooling device 4 is located on one side (+D2 side) in the second direction with respect to the first heat generator 30. The cooling device 4 covers the exhaust port 60a.

The cooling device 4 has a plurality of fans 40. That is, the electronic device 1 includes the plurality of fans 40. In the present embodiment, the cooling device 4 is provided with five fans 40. The plurality of fans 40 are arranged in the first direction D1. That is, the electronic device 1 includes three or more fans 40.

Each of the plurality of fans 40 is an axial fan that takes in air from the other side (−D2 side) in the second direction and sends air to one side (+D2 side) in the second direction. As a result, the cooling device 4 generates an airflow on one side (+D2 side) in the second direction in the housing 60. The plurality of fans 40 are disposed on one side (+D2 side) in the second direction with respect to the plurality of first heat generators 30 and the plurality of second heat generators 10. Therefore, the airflow generated by the fan 40 flows around the first heat generator 30 and the second heat generator 10. Note that the fan 40 is not limited to an axial fan as long as it generates an airflow in the second direction D2 in the housing 60, and may be another type of fan such as a centrifugal fan.

The airflow generated by the action of the cooling device 4 causes the air to enter the housing 60 from the outside of the housing 60 through the intake port 60b. Further, the air passes through the inside of the housing 60 in the order of the second heat generator 10 and the first heat generator 30, and is blown out of the housing 60 through the cooling device 4 and the exhaust port 60a. This air cools the second heat generator 10 in the process of passing around the second heat generator 10, and cools the first heat generator 30 in the process of passing around the first heat generator 30.

According to the present embodiment, among the first heat generator 30 and the second heat generator 10, the first heat generator 30 having a relatively large calorific value is disposed downstream of the second heat generator 10 having a relatively small calorific value. That is, the plurality of heat generators 10 and 30 are arranged in the order of increasing calorific value along the direction of the airflow in the housing 60. As a result, the air warmed by the first heat generator 30 having a large calorific value does not warm the second heat generator 10, and the heat generators 10 and 30 can be reliably cooled. Although not illustrated here, another heat generator may be disposed between the first heat generator 30 and the second heat generator 10 in the second direction. In this case, the calorific value of the heat generator is preferably larger than the calorific value of the second heat generator 10 and smaller than the calorific value of the first heat generator 30.

The airflow restrictor 50 is located between the plurality of first heat generators 30 and the plurality of fans 40 in the housing 60. That is, in the housing 60, the second heat generator 10, the first heat generator 30, the airflow restrictor 50, and the fan 40 are arranged in this order toward one side (+D2 side) in the second direction. The airflow restrictor 50 restricts the flow of air flowing between the plurality of first heat generators 30 and the plurality of fans 40.

The airflow restrictor 50 includes a pair of guide portions 51 and 52. The guide portions 51 and 52 of the present embodiment have a triangular prism shape extending in the third direction D3. The pair of guide portions 51 and 52 are arranged in the first direction D1.

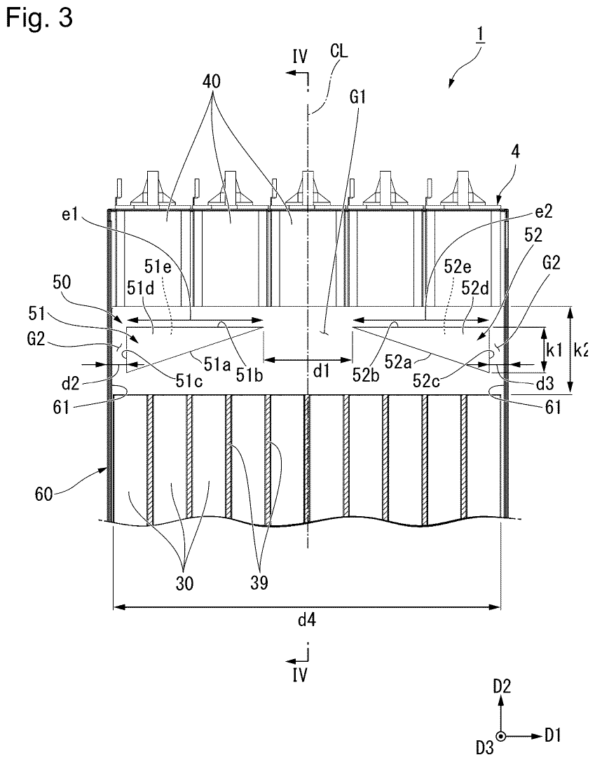

FIG. 3 is a plan view illustrating a part of the electronic device 1 on one side (+D2 side) in the second direction.

As illustrated in FIG. 3, the inner side surface of the housing 60 includes a pair of first inner side surfaces 61 facing each other in the first direction D1. As illustrated in FIG. 3, a center line CL disposed at the center in the first direction D1 and extending in the second direction D2 when the electronic device 1 is viewed from the third direction D3 is assumed. The pair of guide portions 51 and 52 is disposed mirror-symmetrically with respect to the center line CL.

In the following description, when the pair of guide portions 51 and 52 is described to be distinguished from each other, one positioned on the other side (−D1 side) in the first direction is referred to as a first guide portion 51, and the other positioned on one side (+D1 side) in the first direction is referred to as a second guide portion 52.

The first guide portion 51 has an airflow guide surface 51a, a back surface 51b, a side surface 51c, an upper surface 51d, and a lower surface 51e. The airflow guide surface 51a is inclined toward one side (+D2 side) in the second direction as it goes toward one side (+D1 side) in the first direction. The back surface 51b is a surface orthogonal to the second direction D2 and facing the other side (−D2 side) in the second direction. The side surface 51c is a surface orthogonal to the first direction D1 and facing the other side (−D1 side) in the first direction. The upper surface 51d and the lower surface 51e are surfaces facing one side and the other side in the third direction. The airflow guide surface 51a, the back surface 51b, and the side surface 51c are rectangular flat surfaces. The upper surface 51d and the lower surface 51e are triangular flat surfaces.

Similarly, the second guide portion 52 has an airflow guide surface 52a, a back surface 52b, a side surface 52c, an upper surface 52d, and a lower surface 52e. The airflow guide surface 52a is inclined to one side (+D2 side) in the second direction toward the other side (−D1 side) in the first direction. The back surface 52b is a surface orthogonal to the second direction D2 and facing the other side (−D2 side) in the second direction. The side surface 52c is a surface orthogonal to the first direction D1 and facing one side (+D1) in the first direction. The upper surface 52d and the lower surface 52e are surfaces facing one side and the other side in the third direction. The airflow guide surface 52a, the back surface 52b, and the side surface 52c are rectangular flat surfaces. The upper surface 52d and the lower surface 52e are triangular flat surfaces.

A first gap G1 is provided between the first guide portion 51 and the second guide portion 52. That is, the pair of guide portions 51 and 52 is arranged side by side in the first direction D1 with the first gap G1 interposed therebetween. The first gap G1 is located on the center line CL when viewed from the third direction. The first gap G1 is located between a corner formed by the airflow guide surface 51a and the back surface 51b of the first guide portion 51 and a corner formed by the airflow guide surface 52a and the back surface 52b of the second guide portion 52.

The first guide portion 51 and the second guide portion 52 face the first inner side surface 61 of the housing 60 with a gap G2 therebetween. In the present specification, a gap between the first inner side surface 61 and the airflow restrictor 50 is defined as a second gap G2. The pair of second gaps G2 is located on both sides in the first direction D1 with respect to the airflow restrictor 50. The second gap G2 on one side is provided between the side surface 51c of the first guide portion 51 and the first inner side surface 61 located on the other side (−D1 side) in the first direction. The second gap G2 on the other side is provided between the side surface 52c of the second guide portion 52 and the first inner side surface 61 located on one side (+D1 side) in the first direction. In the present embodiment, the dimensions d2 and d3 of the pair of second gaps G2 are equal to each other.

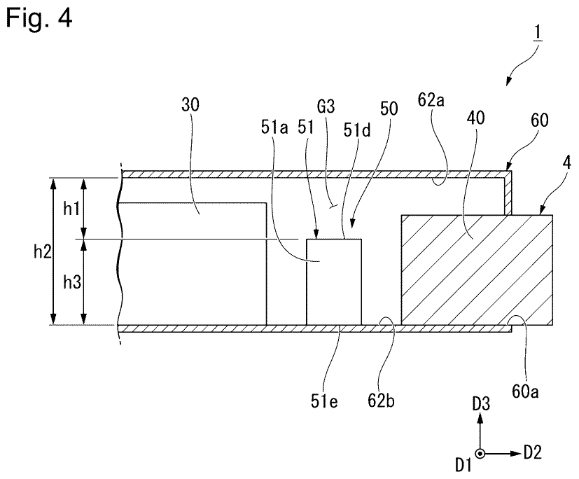

FIG. 4 is a cross-sectional view of the electronic device 1 taken along line IV-IV in FIG. 3.

As illustrated in FIG. 4, the inner side surface of the housing 60 includes a pair of second inner side surfaces 62a and 62b facing each other in the third direction D3. Here, when the pair of second inner side surfaces 62a and 62b is distinguished from each other, one located on the upper side is referred to as a top surface 62a, and the other located on the lower side is referred to as a bottom surface 62b. The bottom surface 62b is an upper surface of the main board on which the first heat generator 30 is mounted.

The lower surface 51e of the first guide portion 51 is fixed to the bottom surface 62b of the housing 60. On the other hand, the upper surface 51d of the first guide portion 51 faces the top surface 62a of the housing 60 with a gap G3. In the present embodiment, a gap between the top surface 62a and the airflow restrictor 50 is defined as a third gap G3. Although not illustrated, the second guide portion 52 is also fixed to the bottom surface 62b on the lower surface 52e similarly to the first guide portion 51, and faces the top surface 62a with the third gap G3 interposed therebetween on the upper surface 52d. A dimension h1 of the third gap G3 in the third direction D3 is uniform over the entire third gap G3. That is, the third gap G3 having the uniform height dimension h1 is provided between the airflow restrictor 50 and the top circle 62a of the present embodiment.

As illustrated in FIG. 3, the airflow guide surfaces 51a and 52a of the pair of guide portions 51 and 52 of the present embodiment face the other side (−D2 side) in the second direction and are inclined toward the first gap G1 side. Therefore, the airflow restrictor 50 generated in the housing 60 by the plurality of fans 40 hits the airflow guide surfaces 51a and 52a and is guided to the first gap G1 side. After passing through the first gap G1, the airflow is sucked into the plurality of fans 40 arranged in the first direction D1. That is, according to the present embodiment, the airflow generated by the plurality of fans 40 is concentrated by the airflow restrictor 50. Therefore, even when the air blowing amount of one of the plurality of fans 40 extremely decreases, it is possible to suppress the local decrease in the air volume in the region facing the fan 40. As a result, it is possible to suppress insufficient cooling of the heat element 32 in the specific first heat generator 30.

The airflow guide surfaces 51a and 52a of the present embodiment are flat surfaces. However, the airflow guide surfaces 51a and 52a may be curved surfaces. In this case, each of the airflow guide surfaces 51a and 52a preferably has a uniform cross section along the third direction. The airflow guide surfaces 51a and 52a are preferably convex curved surfaces.

As described above, most of the airflow in the housing 60 is concentrated in the first gap G1 by the pair of airflow guide surfaces 51a and 52a of the airflow restrictor 50. However, in this case, the airflow is difficult to flow in a region away from the first gap G1, and there is a possibility that the amount of heat radiation of the first heat generator 30 away from the first gap G1 decreases. According to the present embodiment, the gaps G2 and G3 are provided between the airflow restrictor 50 and the inner side surface of the housing 60. Therefore, it is possible to prevent a part of the airflow from passing through the gaps G2 and G3 and flowing to the first heat generator 30 disposed in a region away from the airflow restrictor 50, and to prevent the heat element 32 in the first heat generator 30 away from the first gap G1 from being insufficiently cooled.

In the present embodiment, both the second gap G2 and the third gap G3 are provided in the housing 60, but this effect can be obtained even if either one is provided. That is, a gap may be provided between any one of the pair of first inner side surfaces 61 and the pair of second inner side surfaces 62a and 62b and the airflow restrictor 50. As illustrated in the present embodiment, when both the second gap G2 and the third gap G3 are provided, these effects can be more remarkably obtained.

According to the present embodiment, the guide portions 51 and 52 each have a triangular shape extending in the third direction. According to the present embodiment, rigidity can be enhanced as compared with a plate-shaped guide portion or the like. Accordingly, even when the output of the fan 40 is increased to increase the air volume of the airflow flowing in the housing 60, it is possible to suppress the vibration of the guide portions 51 and 52 due to the influence of the airflow to cause noise.

In the present embodiment, the back surfaces 51b and 52b of the guide portions 51 and 52 extend in a direction orthogonal to the second direction D2. That is, the back surfaces 51b and 52b of the guide portions 51 and 52 do not protrude toward the fan 40. Therefore, a sufficiently wide gap is secured between the guide portions 51 and 52 and the fan 40. By ensuring a gap between the guide portions 51 and 52 and the fan 40, the suction amount of each of the plurality of fans 40 can be stabilized. As a result, the air volume of the airflow flowing in the housing 60 can be easily increased, and the plurality of heat generators 10 and 30 can be efficiently cooled.

As illustrated in FIG. 3, a dimension e1 of the first guide portion 51 in the first direction D1 and a dimension e2 of the second guide portion 52 in the first direction D1 are defined. In the present embodiment, these dimensions e1 and e2 are lengths of the back surfaces 51b of the guide portions 51 and 52 in the first direction D1, respectively. As a matter of course, the sum (e1+e2+d1+d2+d3) of the dimensions e1 and e2 of the pair of guide portions 51 and 52, the dimension d1 of the first gap G1, and the dimensions d2 and d3 of the pair of second gaps G2 in the first direction D1 is equal to the distance d4 between the pair of first inner side surfaces 61 of the housing 60.

In the present embodiment, a ratio ((e1+e2)/d4) of a sum (e1+e2) of the dimensions e1 and e2 of the pair of guide portions 51 and 52 in the first direction D1 to the distance d4 between the pair of first inner side surfaces 61 is preferably 50% or more and 80% or less. The airflow restrictor 50 covers a half or more (that is, 50% or more) of the width dimension in the housing 60 in the first direction D1, so that the airflow is concentrated in the gaps G1 and G2, and the influence of the decrease in the air blowing amount of some fans 40 can be reduced. On the other hand, if the airflow restrictor 50 is made too large in the first direction D1, the air passage resistance at the time of passing through the airflow restrictor 50 extremely increases, and it becomes difficult for a sufficient amount of air to flow into the housing 60. Therefore, the above-described ratio ((e1+e2)/d4) is preferably 80% or less.

In the present embodiment, the ratio (k1/k2) of the dimension k1 of the guide portions 51 and 52 in the second direction D2 to the distance k2 between the fan 40 and the first heat generator 30 in the second direction D2 is preferably 10% or more and 50% or less. By setting the ratio of k1/k2 to 10% or more, the airflow guide surfaces 51a and 52a of the guide portions 51 and 52 can be disposed sufficiently long along the second direction, and the airflow can be easily guided to the first gap G1. By setting the ratio of k1/k2 to 50% or less, it is possible to suppress inhibition of suction of the fan 40 by the guide portions 51 and 52.

In the present embodiment, the dimension d1 of the first gap G1 in the first direction D1 is preferably larger than the dimensions d2 and d3 of the second gap G2 in the first direction D1 (d1>d2, d1>d3). By setting the dimensions of the first gap G1 and the second gap G2 to have such a relationship, it is possible to generate a part of the airflow in the second gap G2 while obtaining the effect of concentrating the airflow by the first gap G1.

The dimension d1 of the first gap G1 in the first direction D1 is preferably larger than the dimension h1 of the third gap G3 in the third direction D3 illustrated in FIG. 3. By setting the dimensions of the first gap G1 and the third gap G3 in such a relationship, it is possible to generate a part of the airflow in the third gap G3 while obtaining the effect of concentrating the airflow by the first gap G1.

In the present embodiment, the ratio (h3/h2) of the dimension h3 of the guide portions 51 and 52 in the third direction D3 to the distance h2 between the pair of second inner side surfaces 62a and 62b is preferably 50% or more and 90% or less. The airflow restrictor 50 covers half or more (that is, 50% or more) of the width dimension in the housing 60 in the third direction D3, so that the airflow is concentrated in the gap G3, and the influence of the decrease in the air blowing amount of some fans 40 can be reduced. On the other hand, if the airflow restrictor 50 is made too large in the third direction D3, the air passage resistance at the time of passing through the airflow restrictor 50 extremely increases, and it becomes difficult for a sufficient amount of air to flow into the housing 60. Therefore, the above-described ratio (h3/h2) is preferably 90% or less.

As illustrated in FIG. 3, in the present embodiment, the seal member 39 is disposed between the first heat generators 30 adjacent to each other. According to the present embodiment, the gap between the first heat generators 30 is closed by the seal member 39. As a result, the air flowing through the housing 60 flows between the fins 33f of the first heat generator 30 without flowing through the gap, and the cooling of the first heat generator 30 is promoted.

The seal member 39 is preferably a heat conductive sheet. The seal member 39 is sandwiched between the first heat generators 30 arranged in the first direction D1 and comes into contact with these first heat generators 30. When the seal member 39 is a thermally conductive sheet, heat can be transferred between the first heat generators 30 adjacent to each other via the seal member 39, and when the temperature of a specific first heat generator 30 increases, heat can be transferred to another first heat generator 30.

The seal member 39 may be a sound absorbing material. In this case, the seal member 39 can reduce noise generated by driving the electronic device 1. As the sound absorbing material, for example, a porous material having a porous structure is exemplified.

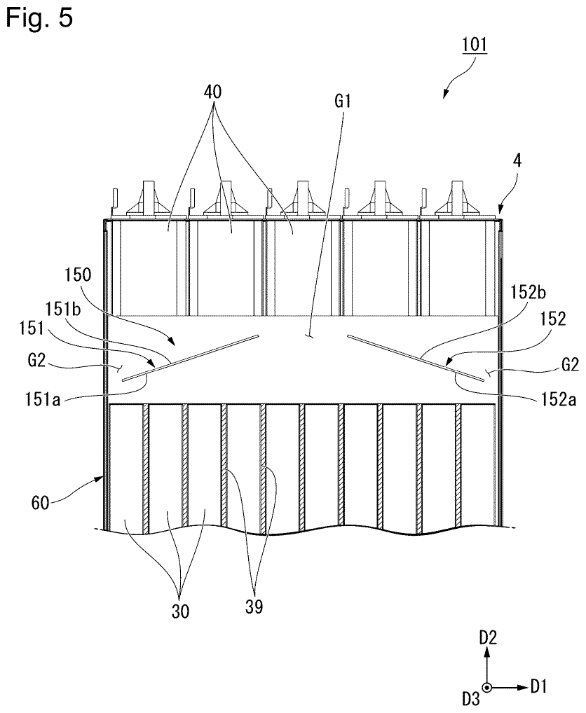

FIG. 5 is a plan view illustrating a part of one side (+D2 side) in the second direction of the electronic device 101 according to the second embodiment. In the description of each embodiment below, the same reference numerals are given to the same components as those of the embodiment already described, and the description thereof will be omitted.

Similarly to the above-described embodiment, the electronic device 101 of the present embodiment includes an airflow restrictor 150 located between the plurality of first heat generators 30 and the plurality of fans 40 in the housing 60. The airflow restrictor 150 includes a pair of guide portions 151 and 152. The pair of guide portions 151 and 152 is disposed mirror-symmetrically when viewed from the third direction. The pair of guide portions 151 and 152 have airflow guide surfaces 151a and 152a, respectively. The gaps G1, G2, and G3 provided between the guide portion 151 and the inner side surface of the housing 60 are also the same as those in the above-described embodiment.

In the present embodiment, the guide portions 151 and 152 have a plate shape with the airflow guide surfaces 151a and 152a as the plate surface direction. By forming the guide portions 151 and 152 in the plate shape, back surfaces 151b and 152b of the guide portions 151 and 152 are separated from the fan 40 as being separated from the gap G1 in the first direction. Therefore, a sufficiently wide gap can be secured between the guide portions 151 and 152 and the fan 40, and the suction amount of each of the plurality of fans 40 can be stabilized. As a result, the air volume of the airflow flowing in the housing 60 can be easily increased, and the plurality of heat generators 10 and 30 can be efficiently cooled.

Although various embodiments of the present invention have been described above, configurations in the respective embodiments and combinations thereof are examples, and thus, addition, omission, replacement of configurations, and other modifications can be made within a range without departing from the spirit of the present invention. Also note that the present invention is not limited by the embodiment.

Note that the present technique can have a configuration below.

(1) An electronic device including: a housing having a box shape with a first direction, a second direction, and a third direction orthogonal to each other as respective plane directions, an exhaust port being provided at an end portion on one side in the second direction, and an intake port being provided at an end portion on an other side in the second direction; a plurality of heat generators arranged in the first direction in the housing; a plurality of fans arranged in the first direction in the housing, arranged on one side in the second direction with respect to the plurality of heat generators, and configured to generate an airflow on one side in the second direction in the housing; and an airflow restrictor positioned between the plurality of heat generators and the plurality of fans in the housing, in which the airflow restrictor includes a pair of guide portions arranged side by side with a first gap interposed therebetween in the first direction, each of the pair of guide portions has an airflow guide surface facing an other side in the second direction and inclined toward the first gap side, an inner side surface of the housing includes: a pair of first inner side surfaces facing each other in the first direction; and a pair of second inner side surfaces facing each other in the third direction, and a gap is provided between any one of the pair of first inner side surfaces and the pair of second inner side surfaces and the airflow restrictor.

(2) The electronic device according to (1), in which the guide portion has a triangular prism shape extending in the third direction.

(3) The electronic device according to (1), in which the guide portion has a plate shape with the airflow guide surface as a plate surface direction.

(4) The electronic device according to any one of (1) to (3), in which a ratio of a sum of dimensions of the pair of guide portions in the first direction to a distance between the pair of first inner side surfaces is 50% or more.

(5) The electronic device according to any one of (1) to (4), in which a ratio of a dimension of the guide portion in the second direction to a distance between the fan and the heat generator in the second direction is 50% or less.

(6) The electronic device according to any one of (1) to (5), in which a gap between the first inner side surface and the airflow restrictor is defined as a second gap, and a dimension of the first gap in the first direction is larger than a dimension of the second gap in the first direction.

(7) The electronic device according to any one of (1) to (6), in which a gap between the second inner side surface and the airflow restrictor is defined as a third gap, and a dimension of the first gap in the first direction is larger than a dimension of the third gap in the third direction.

(8) The electronic device according to any one of (1) to (7), in which a ratio of a dimension of the guide portion in the third direction to a distance between the pair of second inner side surfaces is 50% or more.

(9) The electronic device according to any one of (1) to (8), in which three or more of the fans are provided.

(10) The electronic device according to any one of (1) to (9), in which a seal member is disposed between the heat generators adjacent to each other.

(11) The electronic device according to (10), in which the seal member is a heat conductive sheet.

(12) The electronic device according to (10), in which the seal member is a sound absorbing material.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electronic device comprising:
a housing having a box shape with a first direction, a second direction, and a third direction orthogonal to each other as respective plane directions, an exhaust port being provided at an end portion on one side in the second direction, and an intake port being provided at an end portion on an other side in the second direction;
a plurality of heat generators arranged in the first direction in the housing;
a plurality of fans arranged in the first direction in the housing, arranged on one side in the second direction with respect to the plurality of heat generators, and configured to generate an airflow on one side in the second direction in the housing; and
an airflow restrictor positioned between the plurality of heat generators and the plurality of fans in the housing,
wherein
the airflow restrictor includes a pair of guide portions arranged side by side with a first gap interposed therebetween in the first direction,
each of the pair of guide portions has an airflow guide surface facing an other side in the second direction and inclined toward the first gap side,
an inner side surface of the housing includes:
a pair of first inner side surfaces facing each other in the first direction; and
a pair of second inner side surfaces facing each other in the third direction, and
a gap is provided between any one of the pair of first inner side surfaces and the pair of second inner side surfaces and the airflow restrictor.

2. The electronic device according to claim 1, wherein
the guide portion has a triangular prism shape extending in the third direction.

3. The electronic device according to claim 1, wherein
the guide portion has a plate shape with the airflow guide surface as a plate surface direction.

4. The electronic device according to claim 1, wherein
a ratio of a sum of dimensions of the pair of guide portions in the first direction to a distance between the pair of first inner side surfaces is 50% or more.

5. The electronic device according to claim 1, wherein
a ratio of a dimension of the guide portion in the second direction to a distance between the fan and the heat generator in the second direction is 50% or less.

6. The electronic device according to claim 1, wherein
a gap between the first inner side surface and the airflow restrictor is defined as a second gap, and
a dimension of the first gap in the first direction is larger than a dimension of the second gap in the first direction.

7. The electronic device according to claim 1, wherein
a gap between the second inner side surface and the airflow restrictor is defined as a third gap, and
a dimension of the first gap in the first direction is larger than a dimension of the third gap in the third direction.

8. The electronic device according to claim 1, wherein
a ratio of a dimension of the guide portion in the third direction to a distance between the pair of second inner side surfaces is 50% or more.

9. The electronic device according to claim 1, wherein
three or more of the fans are provided.

10. The electronic device according to claim 1, wherein
a seal member is disposed between the heat generators adjacent to each other.

11. The electronic device according to claim 10, wherein
the seal member is a heat conductive sheet.

12. The electronic device according to claim 10, wherein
the seal member is a sound absorbing material.
